(19) United States
(12) Patent Application Publication
(10) Pub. No.: US 2026/0013180 A1
(43) Pub. Date: Jan. 8, 2026

(54) SEMICONDUCTOR DEVICE

(71) Applicant: Samsung Electronics Co., Ltd., Suwon-si (KR)

(72) Inventors: Sangcheol NA, Suwon-si (KR); Minchan GWAK, Suwon-si (KR); Seungmin CHA, Suwon-si (KR); Kyoungwoo LEE, Suwon-si (KR)

(73) Assignee: Samsung Electronics Co., Ltd., Suwon-si (KR)

(21) Appl. No.: 18/966,843

(22) Filed: Dec. 3, 2024

(30) Foreign Application Priority Data
Jul. 2, 2024 (KR) 10-2024-0086950

(51) Int. Cl. H10D 30/67; H10D 30/00

(52) U.S. Cl. CPC H10D 30/6735; H10D 30/6736; H10D 30/502; H10D 30/6757

(57) ABSTRACT

A semiconductor device may include a substrate insulating layer, a semiconductor pattern extending on the lower insulating pattern, a plurality of channel layers stacked on the semiconductor pattern, a gate structure surrounding the plurality of channel layers, a source/drain region on the semiconductor pattern and opposite sides of the gate structure, a backside contact structure including a contact region connected to the source/drain region, and an intermediate insulating pattern in contact with the semiconductor pattern. The backside contact structure may include a metal-semiconductor compound layer, a first insulating liner layer, a second insulating liner layer, and a conductive layer. The backside contact structure may pass through each of the substrate insulating layer, and the semiconductor pattern. The conductive layer may have a step portion between a first vertical region and a second vertical region of the backside contact structure.

### CROSS-REFERENCE TO RELATED APPLICATION(S)

This application claims benefit of priority to Korean Patent Application No. 10-2024-0086950 filed on Jul. 2, 2024 in the Korean Intellectual Property Office, the disclosure of which is incorporated herein by reference in its entirety.

### BACKGROUND

Inventive concepts relate to a semiconductor device.

As demand for implementation of high performance, high speed, and/or multi-functionalization of semiconductor devices increases, a degree of integration of semiconductor devices has been increasing. In accordance with the trend for a higher degree of integration of semiconductor devices, semiconductor devices, having a backside power delivery network (BSPDN) structure, in which a power rail is disposed on a rear surface of a wafer, have been developed. In order to overcome a limitation of operating properties due to a reduction in size of a planar metal oxide semiconductor FET (MOSFET), semiconductor devices having a three-dimensional channel have been developed.

### SUMMARY

An aspect of inventive concepts provide a semiconductor device having improved electrical properties.

According to an embodiment of inventive concepts, a semiconductor device may include a substrate insulating layer including a lower insulating pattern having a fin structure extending in a first direction; a semiconductor pattern extending in the first direction on the lower insulating pattern of the substrate insulating layer; a plurality of channel layers stacked on the semiconductor pattern and spaced apart from each other in a direction perpendicular to an upper surface of the lower insulating pattern; a gate structure surrounding the plurality of channel layers and extending in a second direction, the second direction intersecting the first direction; a source/drain region on the semiconductor pattern and opposite sides of the gate structure, the source/drain region connected to side surfaces of the plurality of channel layers in the first direction; a backside contact structure below the source/drain region, the backside contact structure including a contact region connected to the source/drain region, a first vertical region vertically extending below the contact region, and a second vertical region vertically extending below the first vertical region; and an intermediate insulating pattern in contact with a lower surface of the semiconductor pattern, the intermediate insulating pattern overlapping a portion of the backside contact structure in a horizontal direction. The backside contact structure may include a metal-semiconductor compound layer, a first insulating liner layer, a second insulating liner layer, and a conductive layer. The metal-semiconductor compound layer may form an external surface of the contact region. The metal-semiconductor compound layer may be in contact with the source/drain region. The first insulating liner layer may form an external surface of the first vertical region. The first insulating liner layer may be in contact with the semiconductor pattern. The second insulating liner layer may form an external surface of the second vertical region. The second insulating liner layer may be in contact with the lower insulating pattern. The conductive layer may pass through each of the substrate insulating layer and the semiconductor pattern. The conductive layer may be in contact with each of the metal-semiconductor compound layer, the first insulating liner layer, and the second insulating liner layer. A step portion of the conductive layer may be between the first vertical region and the second vertical region.

According to an embodiment of inventive concepts, a semiconductor device may include a substrate insulating layer; a semiconductor pattern extending in a first direction on the substrate insulating layer; a gate structure on the substrate insulating layer and extending in a second direction, the second direction intersecting the first direction; source/drain regions on both sides of the gate structure; a backside contact structure below a corresponding one of the source/drain regions, the backside contact structure including a conductive layer passing through the substrate insulating layer and an insulating liner layer surrounding the conductive layer, the conductor layer being electrically connected to the corresponding one of the source/drain regions; and an intermediate insulating pattern between the substrate insulating layer and the semiconductor pattern, the intermediate insulating pattern in contact with a portion of the conductive layer. A portion of the intermediate insulating pattern may be between the substrate insulating layer and the semiconductor pattern and may extend parallel to each of the semiconductor pattern and the substrate insulating layer. The portion of the conductive layer may be in contact with the intermediate insulating pattern may be exposed from the insulating liner layer.

According to an embodiment of inventive concepts, a semiconductor device may include a substrate insulating layer; a semiconductor pattern extending in a first direction on the substrate insulating layer; a gate structure on the substrate insulating layer and extending in a second direction, the second direction intersecting the first direction; source/drain regions on both sides of the gate structure and on the substrate insulating layer; a backside contact structure below a corresponding one of the source/drain region; and an intermediate insulating pattern between the semiconductor pattern and the substrate insulating layer. The backside contact structure may include a conductive layer passing through the semiconductor pattern and an insulating liner layer surrounding a portion of the conductive layer. The conductor layer may be electrically connected to the corresponding one of the source/drain regions. A level of the intermediate insulating pattern may be the same as a level of a portion of the backside contact structure. The intermediate insulating pattern may be on an upper surface of the substrate insulating layer and side surfaces of the substrate insulating layer. The insulating liner layer may include a first insulating liner layer and a second insulating liner layer. A level of the second insulating liner layer may be lower than a level of the first insulating liner layer. The second insulating liner layer may be spaced apart from the first insulating liner layer.

### BRIEF DESCRIPTION OF DRAWINGS

The above and other aspects, features, and advantages of inventive concepts will be more clearly understood from the following detailed description, taken in conjunction with the accompanying drawings, in which:

FIG. 1 is a plan view of a semiconductor device according to an example embodiment of inventive concepts;

FIG. 2A is a cross-sectional view of the semiconductor device of FIG. 1, taken along line I-I′, and FIG. 2B includes cross-sectional views of the semiconductor device of FIG. 1, taken along line II1-II1′ and II2-II2′;

FIG. 3 is a cross-sectional view of a semiconductor device according to an example embodiment of inventive concepts, taken along line I-I′ of FIG. 1;

FIG. 4A is a cross-sectional view of the semiconductor device according to an example embodiment of inventive concepts, taken along line I-I′ of FIG. 1, and FIG. 4B is cross-sectional views of the semiconductor device to the example embodiment of inventive concepts, taken along line II1-II1′ and II2-II2′ of FIG. 1;

FIGS. 5A to 18B are cross-sectional views of sequential processes in a method of manufacturing a semiconductor device according to example embodiments of inventive concepts; and

FIGS. 19A and 19B are cross-sectional views of processes in a method of manufacturing a semiconductor device according to example embodiments of inventive concepts.

### DETAILED DESCRIPTION

Hereinafter, example embodiments of inventive concepts will be described with reference to the accompanying drawings. As used herein, the terms such as “top,” “upper portion,” “upper surface,” “above,” “bottom,” “lower portion,” “lower surface,” “below,” and “side surface” are based on the drawings, and may vary depending on a direction in which a component is actually arranged.

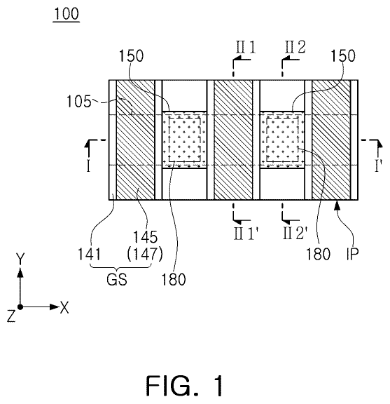

FIG. 1 is a plan view of a semiconductor device 100A according to an example embodiment of inventive concepts.

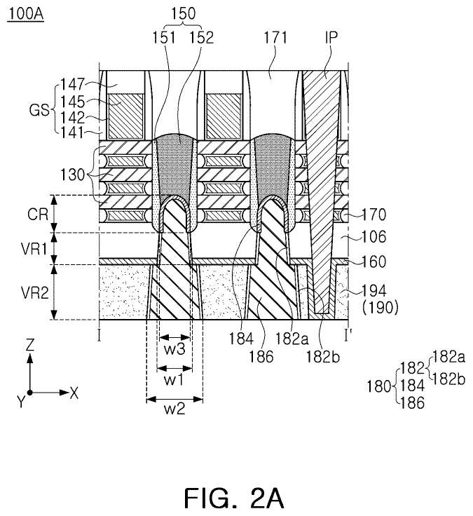

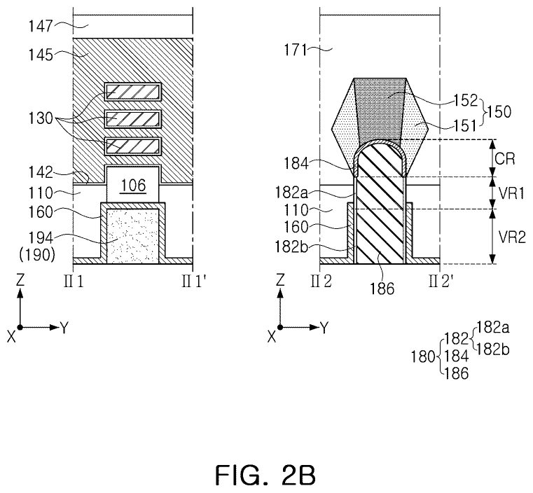

FIG. 2A is a cross-sectional view of the semiconductor device 100A of FIG. 1, taken along line I-I′ of FIG. 1, and FIG. 2B includes cross-sectional views of the semiconductor device 100A of FIG. 1, taken along line II1-II1′ and II2-II2′ of FIG. 1. For ease of description, only main components of the semiconductor device are illustrated in FIGS. 1, 2A, and 2B.

Referring to FIGS. 1, 2A, and 2B, a semiconductor device 100A according to the present example embodiment may include a substrate insulating layer 190 having a lower insulating pattern 194, a semiconductor pattern 106, a plurality of channel layers 130, a gate structure GS, a source/drain region 150, a backside contact structure 180, and an intermediate insulating pattern 160. The semiconductor device 100A according to the present example embodiment may further include an insulating separation pattern IP.

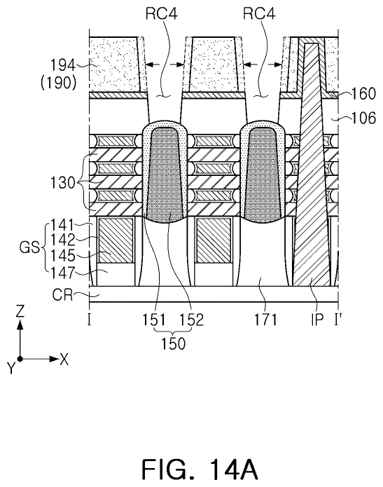

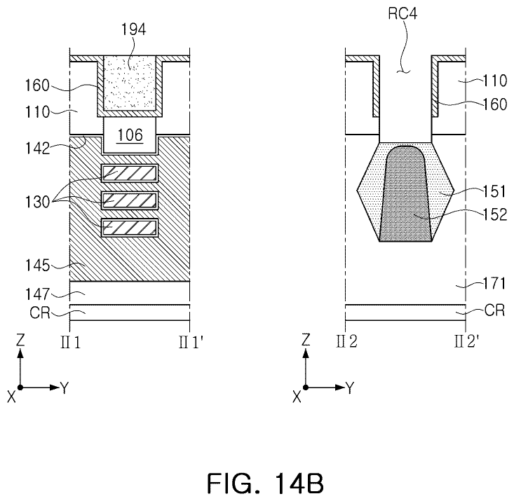

The substrate insulating layer 190 may include the lower insulating pattern 194 having a fin structure extending in a first direction (for example, an X-axis direction). The lower insulating pattern 194 may be understood as a portion defined by a fin-type active structure in the present example embodiment. The lower insulating pattern 194 may be understood as having a bar or fin shape extending in a third direction (for example, a Z-axis direction). The substrate insulating layer 190 may be a layer formed using an additional process after a substrate 101 (see FIGS. 14A and 14B), formed of a semiconductor material, is formed during a manufacturing process. The substrate insulating layer 190 may be formed of an insulating material, and may include, for example, oxide, nitride, or a combination thereof. In some example embodiments, the substrate insulating layer 190 and the lower insulating pattern 194 may include a plurality of insulating layers having materials different from each other.

The semiconductor pattern 106 may be disposed on an upper surface of the lower insulating pattern 194 of the substrate insulating layer 190. The semiconductor pattern 106 may extend in a first direction (for example, an X-direction) on the lower insulating pattern 194, in a similar manner to the lower insulating pattern 194. In plan view, the semiconductor pattern 106 may have a shape substantially corresponding to that of the upper surface of the lower insulating pattern 194. For example, the semiconductor pattern 106 may include at least one of silicon (Si), silicon germanium (SiGe), and germanium (Ge).

The lower insulating pattern 194, the intermediate insulating pattern 160, and the semiconductor pattern 106 may form a single fin-type structure, together with a channel structure including a plurality of channel layers 130. The lower insulating pattern 194, the intermediate insulating pattern 160, and the semiconductor pattern 106 may be sequentially stacked in a direction, perpendicular to an upper surface of the substrate insulating layer 190, to form the fin-type structure. The lower insulating pattern 194 and the semiconductor pattern 106 may have the same width in a second direction (for example, a Y-axis direction), and the intermediate insulating pattern 160 may include a portion extending along an external surface of the fin structure, but a detailed description of the intermediate insulating pattern 160 will be described below. Here, the term “same” may include a process error or the like, and thus may mean that widths in the second direction are not intentionally different from each other.

An isolation layer 110 may define the fin-type structure. The isolation layer 110 may be disposed on the substrate insulating layer 190 to cover at least a portion of a side surface of the semiconductor pattern 106. The isolation layer 110 may include, for example, an oxide film, a nitride film, or a combination thereof. In some example embodiments, the isolation layer 110 may include a deep trench isolation (DTI) region (not illustrated), formed to be deeper than a shallow trench isolation (STI) region defining a fin structure, together with the STI region. The isolation layer 110 may be formed such that an upper region of the fin-type structure, specifically, an upper region of the semiconductor pattern 106, is exposed. In some example embodiments, the isolation layer 110 may have a curved upper surface having a higher level toward the semiconductor pattern 106.

The plurality of channel layers 130 may be disposed on the semiconductor pattern 106 to intersect the gate structures GS. The plurality of channel layers 130 may include two or more layers disposed to be spaced apart from each other in a direction, perpendicular to an upper surface of the semiconductor pattern 106. The plurality of channel layers 130 may be connected to the source/drain regions 150. The plurality of channel layers 130 may have a width equal to or similar to that of the gate structure GS in the first direction (for example, the X-axis direction). In a cross-section of the semiconductor device 100A in the second direction (for example, the Y-axis direction), intersecting the first direction, a lower channel layer, among the plurality of channel layers 130, may have a width equal to or greater than that of an upper channel layer, among the plurality of channel layers 130, but inventive concepts are not limited thereto. In some example embodiments, the plurality of channel layers 130 may have a reduced width as compared to the gate structure GS, such that side surfaces of the plurality of channel layers 130 may be positioned below the gate structure GS in the first direction (for example, the X-direction).

The plurality of channel layers 130 may be formed of a semiconductor material, and may include at least one of, for example, silicon (Si), silicon germanium (SiGe), and germanium (Ge). The plurality of channel layers 130 may be formed of a material the same as that of the semiconductor pattern 106. In some example embodiments, the number and shape of the channel layers may be changed in various manners.

In the semiconductor device 100A, a gate electrode 145 may be disposed between the plurality of channel layers 130 and on the plurality of channel layers 130. Accordingly, the semiconductor device 100A may include a transistor having a multi-bridge channel field effect transistor (MBCFET™) structure, a gate-all-around type field effect transistor.

The gate structures GS may be disposed to extend in one direction, for example, the second direction (Y-axis direction), on the semiconductor pattern 106. Channel regions of transistors may be formed in the plurality of channel layers 130, intersecting the gate electrode 145 of the gate structures GS. The gate structures GS may be disposed to be spaced apart from each other in the first direction (for example, the X-axis direction). Each of the gate structures GS may include gate dielectric layers 142, gate spacer layers 141, and a gate electrode 145. In example embodiments, each of the gate structures GS may further include a gate capping layer 147 on an upper surface of the gate electrode 145.

The gate dielectric layers 142 may be disposed between the semiconductor pattern 106 and the gate electrode 145 and between the plurality of channel layers 130 and the gate electrode 145, and may be disposed to cover at least a portion of surfaces of the gate electrode 145. For example, the gate dielectric layers 142 may be disposed to surround surfaces of the gate electrode 145, excluding an uppermost surface. The gate dielectric layers 142 may extend to a space between the gate electrode 145 and the gate spacer layers 141, but inventive concepts are not limited thereto. The gate dielectric layer 142 may include oxide, nitride, or a high-κ material. The high-κ material may refer to a dielectric material having a dielectric constant, higher than that of a silicon oxide film (SiO₂). The high-κ material may include, for example, one of aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), and praseodymium oxide (Pr₂O₃). In some example embodiments, the gate dielectric layer 142 may have a multilayer structure.

The gate electrode 145 may include a conductive material, for example, a metal nitride such as a titanium nitride film (TiN), a tantalum nitride film (TaN), or a tungsten nitride film (WN), and/or a metal material such as aluminum (Al), tungsten (W), or molybdenum (Mo), or a semiconductor material such as doped polysilicon. In some example embodiments, the gate electrode 145 may have a multilayer structure. In a region not illustrated, the gate electrodes 145 may be connected to upper contact plugs disposed thereon.

The gate spacer layers 141 may be disposed on opposite side surfaces of the gate electrode 145, on the plurality of channel layers 130. The gate spacer layers 141 may insulate the source/drain regions 150 and the gate electrodes 145 from each other. In some example embodiments, shapes of the upper ends of the gate spacer layers 141 may be changed in various manners, and the gate spacer layers 141 may have a multilayer structure. The gate spacer layers 141 may include at least one of oxide, nitride, and oxynitride, and may be formed of, for example, a low-κ film. The gate capping layer 147 may be disposed on an upper portion of the gate electrode 145, and a lower surface and side surfaces of the gate capping layer 147 may be surrounded by the gate electrode 145 and the gate spacer layers 141, respectively.

In an example embodiment of inventive concepts, internal spacer layers 170 may be disposed on opposite sides of the gate structure GS in the first direction (for example, the X-axis direction) and internal spacer layers 170 on a lower surface of each of a plurality of channel layers 130 may be further included. The internal spacer layers 170 may be disposed to be parallel to the gate electrode 145, between the plurality of channel layers 130. The internal spacer layers 170 may be in contact with the gate dielectric layer 142. The internal spacer layers 170 may be disposed between the gate structure GS and the source/drain regions 150. Side surfaces of the internal spacer layers 170 may be in contact with the source/drain region 150. Below each of the plurality of channel layers 130, the gate electrode 145 may be spaced apart from the source/drain region 150 by the internal spacer layers 170 to be electrically isolated from the source/drain region 150. Side surfaces of the internal spacer layers 170, opposing the gate electrode 145, may have an inwardly convex rounded shape toward the gate electrode 145. The internal spacer layers 170 may be formed of oxide, nitride, and oxynitride, and in particular, may be formed of a low-κ film.

The internal spacer layers 170 may be formed of a material the same as that of the gate spacer layers 141, but inventive concepts are not limited thereto. For example, the internal spacer layers 170 may include at least one of SiN, SiCN, SiOCN, SiBCN, and SiBN. The internal spacer layers 170 may be applied to other example embodiments.

The source/drain regions 150 may be disposed on the semiconductor pattern 106, on opposite sides of the gate structures GS, and may be disposed to contact the channel structures 140, respectively. The source/drain regions 150 may be connected to side surfaces of the plurality of channel layers 130 in the first direction (for example, the X-axis direction). The source/drain region 150 may be provided as a source region or a drain region of a transistor. The source/drain regions 150 may be disposed to be spaced apart from each other in the first direction (for example, the X-direction) with respect to one gate structure GS. The source/drain regions 150 may be connected to the backside contact structure 180 through lower surfaces or lower ends thereof. A lower region of the source/drain region 150 may have a recessed shape by the backside contact structure 180. The source/drain region 150 may be electrically connected to a power transmission structure through the backside contact structure 180 to receive power. Upper surfaces of the source/drain regions 150 may be positioned at a height the same as or similar to that of a lower surface of the gate electrode 145 on the plurality of channel layers 130, and the height may be changed in various manners in example embodiments.

The source/drain regions 150 may include a semiconductor material, for example, at least one of silicon (Si) and germanium (Ge), and may further include impurities. The first and second epitaxial layers 151 and 152 may have different compositions. A concentration of a non-silicon element of the second epitaxial layer 152 may be higher than a concentration of the non-silicon element of the first epitaxial layer 152. The non-silicon element may be, for example, germanium (Ge) and/or a doping element.

In the second epitaxial layer 152, a doping concentration of a doping element, that is, impurities, may be higher than that of the first epitaxial layer 151. Accordingly, a specific resistance of the second epitaxial layer 152 may be less than that of the first epitaxial layer 151. When the semiconductor device 100A is a pFET, the impurities may be at least one of boron (B), gallium (Ga), and indium (In). When the semiconductor device 100A is an nFET, the impurities may be at least one of phosphorus (P), arsenic (As), and antimony (Sb). For example, a concentration of boron (B) of the first epitaxial layer 151 may be within a range from about 1×10¹⁶/cm³ to about 1×10²¹/cm³, and a concentration of boron (B) of the second epitaxial layer 152 may be within a range from about 1×10¹⁹/cm³ to about 1×10²²/cm³. According to example embodiments, the source/drain region 150 may include a plurality of regions including elements and/or doping elements having different concentrations. A cross-section of the source/drain region 150 in the second direction (for example, the Y-axis direction) may have a circular shape, an elliptical shape, a pentagonal shape, a hexagonal shape, or a shape similar thereto. However, in example embodiments, the source/drain region 150 may have various shapes, and for example, may have one of a polygonal shape, a circular shape, and a rectangular shape.

The backside contact structure 180 may include a contact region CR connected to the source/drain region 150 below the source/drain region 150, a first vertical region VR1 vertically extending below the contact region CR, and a second vertical region VR2 vertically extending below the first vertical region VR1.

The contact region CR may include a region passing through the first epitaxial layer 151 and the second epitaxial layer 152, the region in contact with the source/drain region 150. A portion of a surface of the contact region CR may be in contact with the first epitaxial layer 151, and another portion of the surface of the contact region CR may be in contact with the second epitaxial layer 152. A level of a lower end of the contact region CR may be the same as or lower than a level of a lower end of the source/drain region 150.

The vertical regions VR1 and VR2 may include a first vertical region VR1 in contact with the lower end of the contact region CR, and a second vertical region VR2 in contact with a lower end of the first vertical region VR1. The first vertical region VR1 may pass through at least a portion of the semiconductor pattern 106 and vertically extend, and the second vertical region VR2 may pass through at least a portion of the lower insulating pattern 194 and vertically extend. The vertical regions VR1 and VR2 may have tapered structures such that widths thereof decrease toward the source/drain region 150. The vertical regions VR1 and VR2 may be positioned below the source/drain region 150.

The first vertical region VR1 may have a first width w1, and the second vertical region VR2 may have a second width w2 greater than the first width w1. The first width w1 may be a region adjacent to the second vertical region VR2 or a width of the lower end of the first vertical region VR1, and the second width w2 may be a region adjacent to the first vertical region VR1 or a width of an upper end of the second vertical region VR2. The contact region CR may have a third width w3 less than the first width w1. The third width w3 may be a region adjacent to the first vertical region VR1 or a width of the lower end of the contact region CR.

The backside contact structure 180 may have an inclined side surface having an upper portion having a width becoming narrower than a width of a lower portion according to an aspect ratio, but inventive concepts are not limited thereto. A width of another region of the backside contact structure 180 may continuously increase toward a lower portion thereof, but inventive concepts are not limited thereto.

In a backside contact structure, among vertical regions vertically extending while passing through a semiconductor pattern or a substrate insulating layer, a second vertical region VR2 having an upper end having an increased width may be introduced, thereby improving resistance of a semiconductor device. As a result, the semiconductor device may have improved electrical properties.

The backside contact structure 180 may a metal-semiconductor compound layer 184 forming an external surface of the contact region CR, the metal-semiconductor compound layer 184 in contact with the source/drain region 150, a first insulating liner layer 182a forming an external surface of the first vertical region VR1, the first insulating liner layer 182a in contact with at least a portion of the semiconductor pattern 106, a second insulating liner layer 182b forming an external surface of the second vertical region VR2, the second insulating liner layer 182b in contact with at least a portion of the lower insulating pattern 194, and a conductive layer 186 passing through at least a portion of each of the lower insulating pattern 194 and the semiconductor pattern 106, the conductive layer 186 in contact with each of the metal-semiconductor compound layer 184, the first insulating liner layer 182a, and the second insulating liner layer 182b.

The metal-semiconductor compound layer 184 may be positioned on an upper end of the backside contact structure 180, and may form at least a part of an upper surface of the backside contact structure 180. The metal-semiconductor compound layer 184 may be positioned on a surface of the contact region CR in contact with the source/drain region 150. The metal-semiconductor compound layer 184 may be disposed in a region in which at least the backside contact structure 180 is in contact with the second epitaxial layer 152. However, in example embodiments, a range of the metal-semiconductor compound layer 184 is not limited to that illustrated. The metal-semiconductor compound layer 184 may be, for example, a metal silicide layer. In some example embodiments, the metal-semiconductor compound layer 184 may be omitted.

The conductive layer 186 may be disposed to fill a contact hole surrounded by a liner layer 182 and the metal-semiconductor compound layer 184. The conductive layer 186 may include, for example, a metal material such as aluminum (Al), tungsten (W), or molybdenum (Mo). The conductive layer 186 may be disposed below the source/drain region 150, may be electrically connected to the source/drain region 150, and may serve as a passage for applying a wave source or a ground voltage from a backside power structure. In example embodiments, the number and arrangement of conductive layers, included in the backside contact structure 180, may be changed in various manners. The conductive layer 186 may have a step portion between the first vertical region VR1 and the second vertical region VR2.

The insulating liner layer 182 may include a first insulating liner layer 182a positioned in the first vertical region VR1, and a second insulating liner layer 182b positioned in the second vertical region VR2. The first insulating liner layer 182a and the second insulating liner layer 182b may form external surfaces of the backside contact structure 180 in the first vertical region VR1 and the second vertical region VR2, respectively. A thickness of the insulating liner layer 182 may be 4 nm to 9 nm, 5 nm to 7 nm, or 5.5 nm to 6.5 nm, but inventive concepts are not limited thereto. The insulating liner layer 182 may include an insulating material formed of oxide, nitride, or oxynitride. In an example embodiment, the insulating liner layer 182 may include an insulating material such as silicon nitride (SiN), but inventive concepts are not limited thereto. An upper surface of the first insulating liner layer 182a may be in contact with a lower surface of the metal-semiconductor compound layer 184, and an upper surface of the second insulating liner layer 182b may be disposed to be spaced apart from a lower surface of the first insulating liner layer 182a. The insulating liner layer 182 may form an external surface of the backside contact structure 180 and surround the conductive layer 186 filling the backside contact structure 180 to prevent the conductive layer 186 including a conductive material from being in contact with the semiconductor pattern 106 including a semiconductor material, thereby electrically insulating the conductive layer 186 and the semiconductor pattern 106 from each other.

The intermediate insulating pattern 160 may extend in the first direction (for example, the X-axis direction) on the substrate insulating layer 190. The intermediate insulating pattern 160 may be disposed on a level, the same as that of at least a portion of the backside contact structure 180, and the intermediate insulating pattern 160 may be disposed to overlap at least a portion of the backside contact structure 180 in a horizontal direction. The intermediate insulating pattern 160 may include a region disposed between the lower insulating pattern 194 of the substrate insulating layer 190 and the semiconductor pattern 106, and a region surrounding at least a portion of each of upper and side surfaces of the lower insulating pattern 194 on a plane. At least a portion of the intermediate insulating pattern 160 may be covered by the isolation layer 110. The intermediate insulating pattern 160 may be formed of a low-κ material, and may be formed of a material having a selectivity with silicon (Si). The intermediate insulating pattern 160 may include, for example, at least one of SiO, SiN, SiCN, SiOC, SiON, and SiOCN, but inventive concepts are not limited thereto. A lower surface of the intermediate insulating pattern 160 may be positioned on a level, lower than that of a lowermost end of each of the source/drain regions 150.

At least a portion of the conductive layer 186 may be exposed from the insulating liner layer 182 covering an external side of the conductive layer 186, and the portion of the conductive layer 186 may be in contact with the intermediate insulating pattern 160. The intermediate insulating pattern 160 may be in contact with the exposed portion of the conductive layer 186, and may be in contact with at least a portion of a side surface of the first insulating liner layer 182a and an upper surface of the second insulating liner layer 182b. The conductive layer 186 may have a step portion at an interface between the first vertical region VR1 and the second vertical region VR2 of the back side contact structure 180. A structure may be provided in which the intermediate insulating pattern 160 is in contact with the exposed portion of the conductive layer 186, thereby electrically insulating the conductive layer 186 and the semiconductor pattern 106 from each other in the present example embodiment.

The insulating separation pattern IP may extend in the second direction (for example, the Y-axis direction) on the substrate insulating layer 190, and the insulating separation pattern IP may extend to be parallel to the gate structure GS. The insulating separation pattern IP may serve to insulate electrical signals between transistors. The insulating separation pattern IP may pass through at least a portion of each of the semiconductor pattern 106 and the lower insulating pattern 194 and extend in the third direction (for example, the Z-axis direction). A lower surface of the insulating separation pattern IP may be positioned on a level, the same as that of a lower surface of the isolation layer 110, but inventive concepts are not limited thereto. The insulating separation pattern IP may include an insulating material, and may include, for example, oxide, nitride, oxynitride, or a combination thereof. The insulating separation pattern IP may pass through a portion of the plurality of channel layers 130 and may serve to insulate electrical signals between opposite sides of the insulating separation pattern IP. The intermediate insulating pattern 160 may cover the lower surface of the insulating separation pattern IP, and may cover at least a portion of a side surface of the insulating separation pattern IP.

The interlayer insulating layer 171 may be disposed to cover the source/drain regions 150, the gate structure GS, and the isolation layer 110. The interlayer insulating layer 171 may include at least one of, for example, oxide, nitride, oxynitride, and a low-κ dielectric.

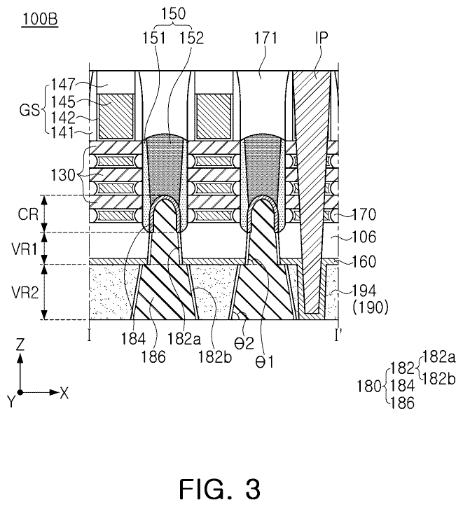

FIG. 3 is a cross-sectional view of a semiconductor device 100B according to an example embodiment of inventive concepts, taken along line I-I′ of FIG. 1.

Referring to FIG. 3, the semiconductor device 100B according to an example embodiment may have features the same as or similar to those described with reference to FIGS. 1 to 2B, except that an angle, formed by a lower surface and a side surface of the second vertical region VR2, and an angle, formed by a lower surface and a side surface of the first vertical region VR1, are different from each other. In the semiconductor device 100B, an angle θ2, formed by a lower surface and a side surface of the second vertical region VR2, may be less than an angle θ1, formed by a lower surface and a side surface of the first vertical region VR1. Virtual extension lines of a second insulating liner layer 182b and a first insulating liner layer 182a may not be parallel to each other. A lower end of the second vertical region VR2 may be further expanded than a lower end of the second vertical region VR2 in the semiconductor device 100A (see FIG. 2A) according to an example embodiment. The semiconductor device 100B according to the present example embodiment may have a structure in which the second vertical region VR2 is expanded, thereby improving a resistance-related issue caused by an aspect ratio of a backside contact structure 180.

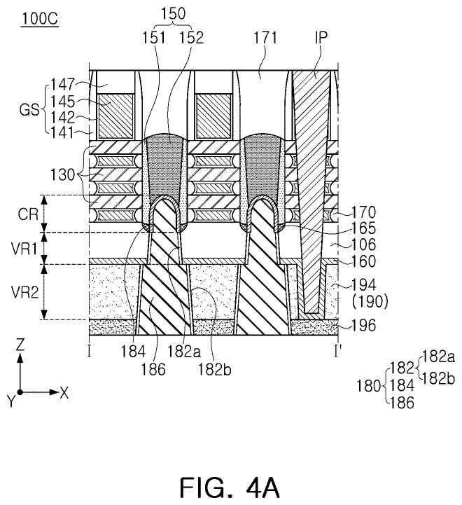

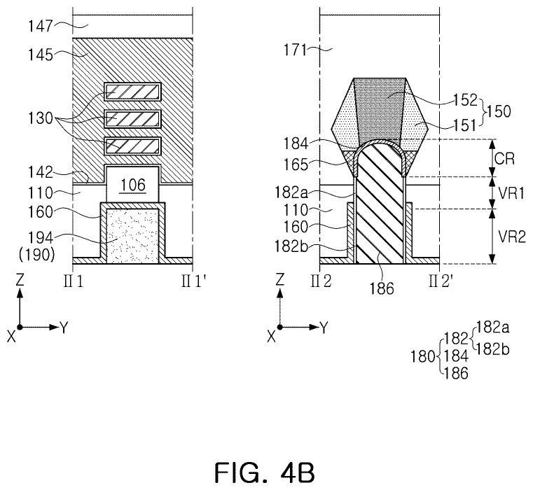

FIG. 4A is a cross-sectional view of a semiconductor device 100C according to an example embodiment of inventive concepts, taken along line I-I′ of FIG. 1, and FIG. 4B is cross-sectional views of a semiconductor device 100C according to an example embodiment of inventive concepts, taken along line II1-II1′ and II2-II2′ of FIG. 1.

Referring to FIGS. 4A and 4B, the semiconductor device 100C according to an example embodiment may have features the same as or similar to those described with reference to FIGS. 1 to 3, except that the semiconductor device 100C further includes a lower material layer 165 on a lower end of a source/drain region 150, and a lower insulating layer 196 below a substrate insulating layer 190. The semiconductor device 100C may further include the lower material layer 165 disposed between the source/drain region 150 and a semiconductor pattern 106. The lower material layer 165 may correspond to a semiconductor material layer including silicon germanium (Ge) or the like, but inventive concepts are not limited thereto. The lower material layer 165 may include a high concentration of impurities (e.g., higher concentration of impurities than the semiconductor pattern 106 and/or source/drain region 150), and the impurities may include an element such as boron (B) or carbon (C). In an example embodiment, the lower material layer 165 may include an insulating material such as SiO, SiN, SiCN, SiOC, SiON, and SiOCN. The lower material layer 165, including a material having a selectivity different from that of each of the semiconductor pattern 106 and the source/drain region 150, may be introduced to serve to protect the source/drain region 150 from being etched during a process of forming a backside contact structure 180, may correspond to a high-resistance layer including a high concentration of impurities or an insulating material, and may be disposed between the source/drain region 150 and the semiconductor pattern 106, thereby electrically insulating the source/drain region 150 and the semiconductor pattern 106 from each other.

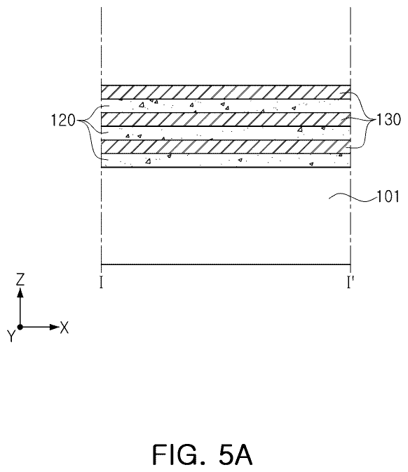

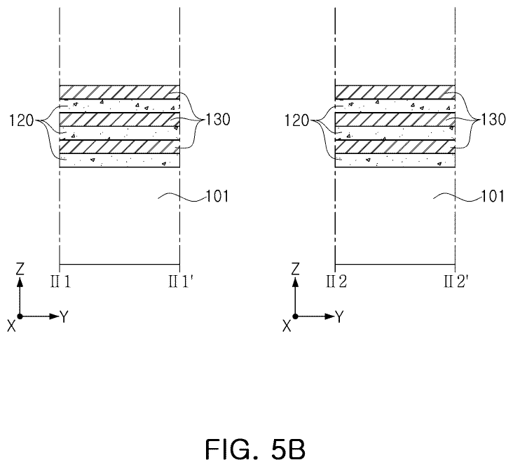

FIGS. 5A to 18B are diagrams illustrating sequential processes in a method of manufacturing a semiconductor device according to example embodiments. FIGS. 5A to 18B illustrate cross-sections corresponding to FIGS. 2A and 2B.

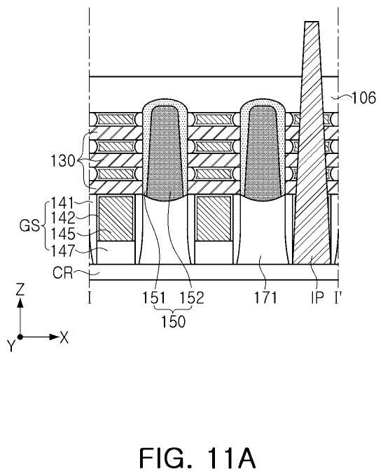

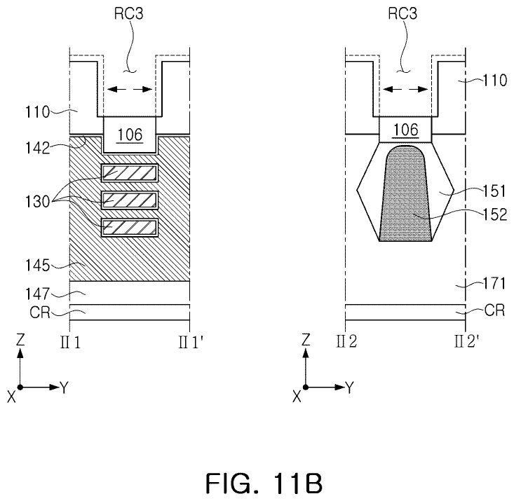

FIGS. 5A to 10B are cross-sectional views of some processes (processes of forming a source/drain region and a gate structure) in a method of manufacturing a semiconductor device according to an example embodiment of inventive concepts, and FIGS. 11A to 18B are cross-sectional views of other processes (processes of forming an intermediate insulating pattern and a backside contact structure) in a method for manufacturing a semiconductor device according to an example embodiment of inventive concepts. Specifically, FIGS. 5A to 10B are cross-sectional views of a frontside process, and FIGS. 11A to 18B are cross-sectional views of a backside process.

Referring to FIGS. 5A and 5B, sacrificial layers 120 and a plurality of channel layers 130 may be alternately stacked on a substrate 101.

The substrate 101 may include silicon (Si), germanium (Ge), or silicon germanium (SiGe). The substrate 101 may include a bulk wafer, an epitaxial layer, a silicon-on-insulator (SOI) layer, or a semiconductor-on-insulator (SeOI) layer.

The sacrificial layers 120 may be layers replaced with gate dielectric layers 142 and gate electrodes 145 below an uppermost channel layer 130 among the plurality of channel layers 130 using a subsequent process, as illustrated in FIG. 2A. The sacrificial layers 120 may be formed of a material having an etch selectivity with respect to each of the plurality of channel layers 130. The plurality of channel layers 130 may include a material different from that of the sacrificial layers 120. The sacrificial layers 120 and the plurality of channel layers 130 may include a semiconductor material including at least one of, for example, silicon (Si), silicon germanium (SiGe), and germanium (Ge), and may or may not include impurities. For example, the sacrificial layers 120 may include silicon germanium (SiGe), and the plurality of channel layers 130 may include silicon (Si).

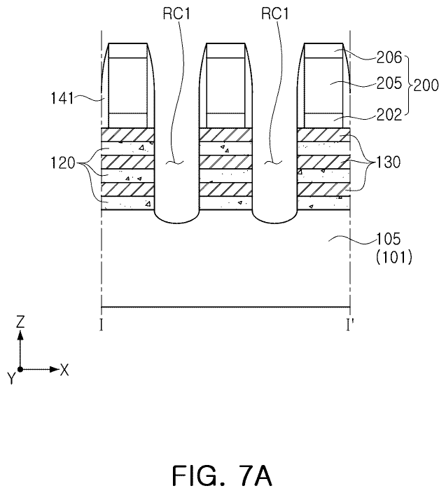

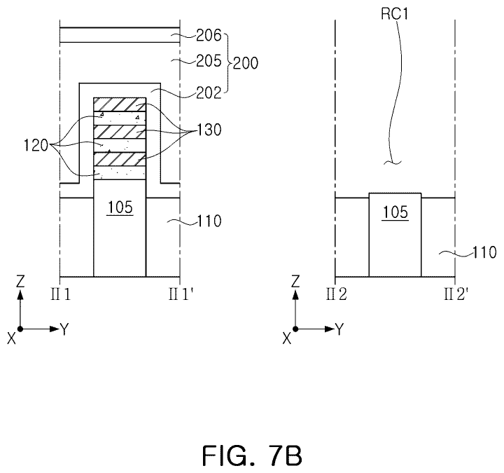

The sacrificial layers 120 and the plurality of channel layers 130 may be formed by performing an epitaxial growth process from the stack structure. FIGS. 7A and 7B illustrates that the number of channel layers stacked alternately with the sacrificial layers 120 is three, but may be changed in various manners in example embodiments.

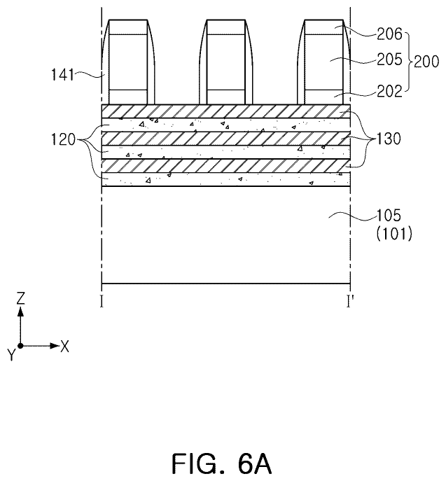

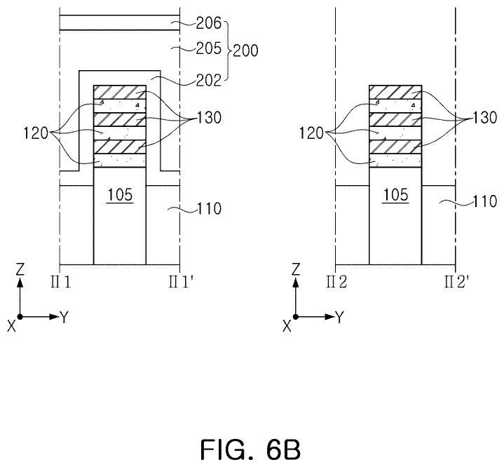

Referring to FIGS. 6A and 6B, an active structure including an active region 105 may be formed by partially removing the sacrificial layers 120, the plurality of channel layers 130, and the substrate 101, an isolation layer 110 may be formed, and a sacrificial gate structure 200 and gate spacer layers 141 may be formed on the active structure.

The active structure may include the active region 105, the sacrificial layers 120, and the plurality of channel layers 130. The active structure may be in the form of a line extending in a first direction (for example, an X-axis direction), and may be formed to be spaced apart from an adjacent active structure in a second direction (for example, a Y-axis direction), intersecting the first direction. Side surfaces of the active structure in the second direction may be coplanar with each other, and may be positioned on a straight line.

In a region from which a portion of each of the active region 105, the sacrificial layers 120, and the plurality of channel layers 130 is partially removed, the isolation layer 110 may be formed by filling an insulating material and then removing the insulating material such that the active region 105 protrudes. An upper surface of the isolation layer 110 may be formed to be lower than an upper surface of the active region 105.

The sacrificial gate structure 200 may be a sacrificial structure formed in a region in which the gate dielectric layer 142 and the gate electrode 145 are disposed on the plurality of channel layers 130 using a subsequent process, as illustrated in FIG. 2. The sacrificial gate structure 200 may be in the form of a line, intersecting the active structure and extending in one direction. The sacrificial gate structures 200 may extend in the second direction (for example, the Y-axis direction), and may be disposed to be spaced apart from each other in the first direction (for example, the X-axis direction).

The sacrificial gate structure 200 may include first and second sacrificial gate layers 202 and 205 and a mask pattern layer 206, sequentially stacked. The first and second sacrificial gate layers 202 and 205 may be patterned using a mask pattern layer 206. The first and second sacrificial gate layers 202 and 205 may be an insulating layer and a conductive layer, respectively, but inventive concepts are not limited thereto, and the first and second sacrificial gate layers 202 and 205 may be formed as a single layer. For example, the first sacrificial gate layer 202 may include silicon oxide, and the second sacrificial gate layer 205 may include polysilicon. The mask pattern layer 206 may include silicon oxide and/or silicon nitride.

The gate spacer layers 141 may be formed on opposite sidewalls of the sacrificial gate structures 200. The gate spacer layers 141 may be formed of a low-κ material, and may include at least one of SiO, SiN, SiCN, SiOC, SiON, and SiOCN.

Referring to FIGS. 7A and 7B, the sacrificial layers 120, exposed from the sacrificial gate structures 200, and the sacrificial layers 120 and the plurality of channel layers 130 may be partially removed to form first recess regions RC1.

A portion of the exposed sacrificial layers 120 and a portion of the plurality of channel layers 141, 142, 143, and 144 may be removed using the sacrificial gate structures 200 and the gate spacer layers 141 as masks to form recess regions RC. Accordingly, the plurality of channel layers 130 may form channel structures having a limited length in the first direction (for example, the X-axis direction).

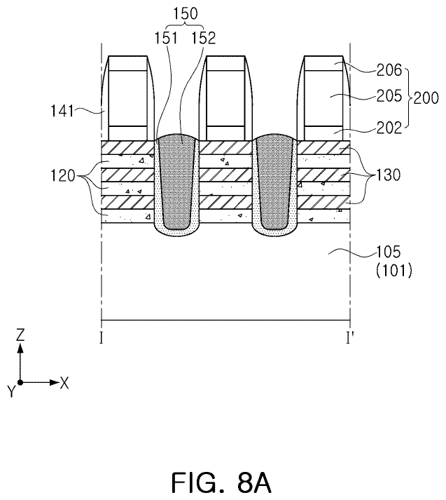

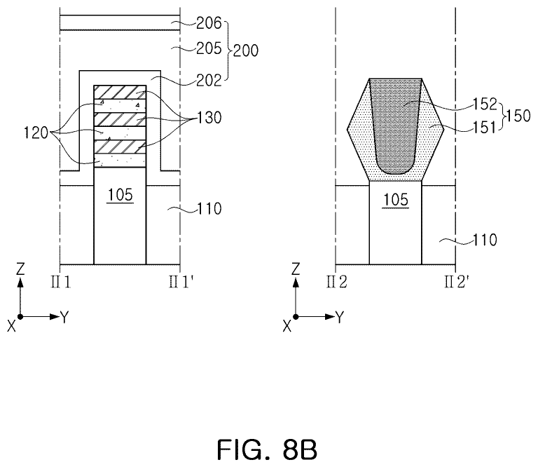

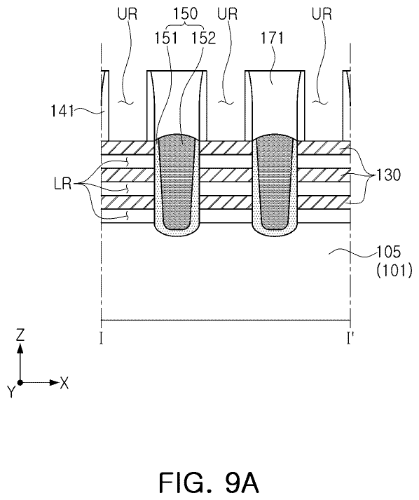

The sacrificial layers 120 may be selectively etched with respect to the channel structures 140 using, for example, a wet etching process, and may be removed from side surfaces thereof in the first direction to a desired and/or alternatively predetermined depth. The sacrificial layers 120 may have inwardly concave side surfaces by etching the side surfaces as described above. However, a specific shape of the side surfaces of the sacrificial layers 120 is not limited to that illustrated in FIGS. 8A and 8B.

Referring to FIGS. 8A and 8B, the source/drain regions 150 may be formed to fill the first recess regions RC1.

The source/drain region 150 may be grown and formed from an upper surface of the active pattern 105 and side surfaces of a plurality of channel layers 130 using, for example, a selective epitaxial process. The first and second epitaxial layers 151 and 152, forming the source/drain region 150, may be sequentially formed. The first and second epitaxial layers 151 and 152 may include impurities by in-situ doping, and may have different compositions and/or doping concentrations.

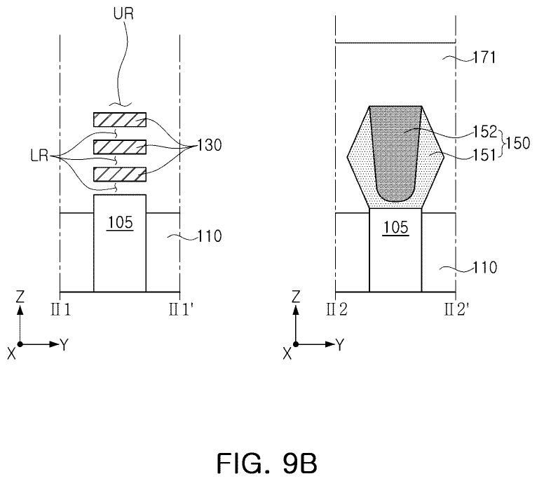

Referring to FIGS. 9A and 9B, an interlayer insulating layer 171 may be partially formed, and the sacrificial gate structures 200 and the sacrificial layers 120 may be removed.

The interlayer insulating layer 171 may be formed by forming an insulating film covering the sacrificial gate structures 200 and the source/drain regions 150 and performing a planarization process thereon.

The sacrificial gate structures 200 and the sacrificial layers 120 may be selectively removed with respect to the gate spacer layers 141, the interlayer insulating layer 192, and the plurality of channel layers 130. First, the sacrificial gate structures 200 may be removed to form upper gap regions UR, and then the sacrificial layers 120, exposed through the upper gap regions UR, may be removed to form lower gap regions LR.

For example, when the sacrificial layers 120 include silicon germanium (SiGe) and the plurality of channel layers 130 include silicon (Si), the sacrificial layers 120 may be selectively removed with respect to the plurality of channel layers 130 by performing a wet etching process. For example, when the sacrificial layers 120 include a first concentration (relatively high concentration) of germanium (Ge) and the first epitaxial layer 151 includes a second concentration (relatively low concentration) of germanium (Ge), the sacrificial layers 120 may be selectively removed with respect to the first epitaxial layer 151.

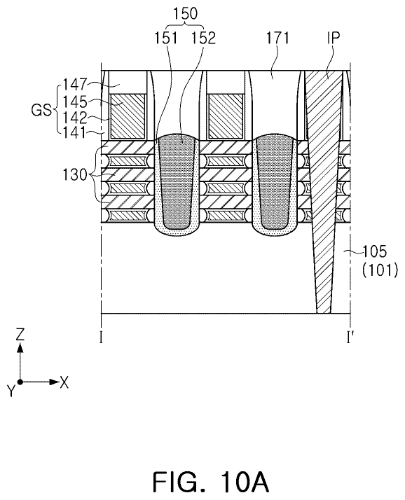

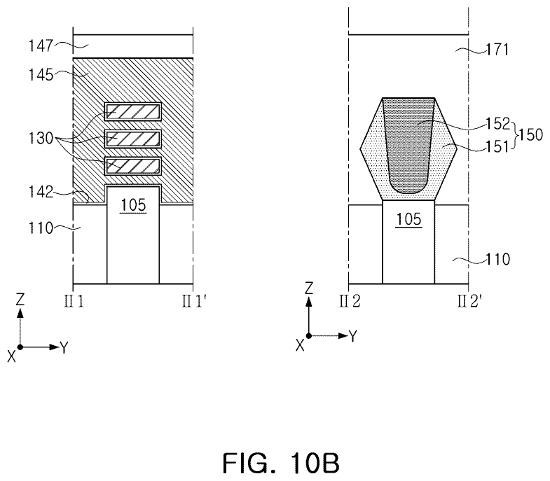

Referring to FIGS. 10A and 10B, the gate dielectric layers 142 and the gate electrode 145 may be formed to form gate structures GS, and an insulating separation pattern IP, extending to be parallel to the gate structures GS, may be formed.

The gate dielectric layers 142 and the gate electrode 145 may be formed to fill the upper gap regions and the lower gap regions. The gate dielectric layers 142 may be formed to conformally cover internal surfaces of the upper gap regions and the lower gap regions. The gate electrode 145 may be formed to entirely fill the upper gap regions and the lower gap regions, and then removed from the upper gap regions to a desired and/or alternatively predetermined depth, together with the gate dielectric layers 142 and the gate spacer layers 141.

Referring to FIGS. 11A and 11B, the entire structure formed with reference to FIGS. 5A to 10B may be attached to a carrier substrate CR, the substrate 101 may be thinned to expose a portion of the insulating separation pattern IP, and a portion of the isolation layer 110 may be removed to form a third recess region RC3.

First, although not specifically illustrated, contact plugs and interconnection lines, connected to the gate structures GS, may be further formed on the gate structures GS. The carrier substrate SUB may be attached to the interlayer insulating layer 171 to perform a process on a lower surface of the substrate 101 illustrated in FIGS. 11A and 11B. In the following drawings, for better understanding, it is illustrated that the entire structure is rotated or inverted in the form of a mirror image of the structure illustrated in FIGS. 10A and 10B.

The substrate 101 may be removed from an upper surface of the substrate 101. The substrate 101 may be removed by performing, for example, a wrapping, grinding, or polishing process to be thinned. A portion of the active pattern 105 may be removed to form a semiconductor pattern 106 having a constant depth from the source/drain region 150. In a process of forming the semiconductor pattern 106, at least a portion of each of a lower surface and side surfaces of the isolation layer 110 may be exposed.

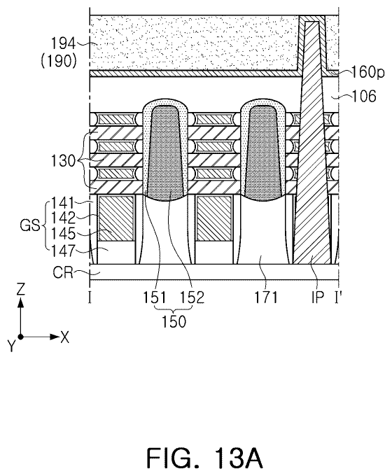

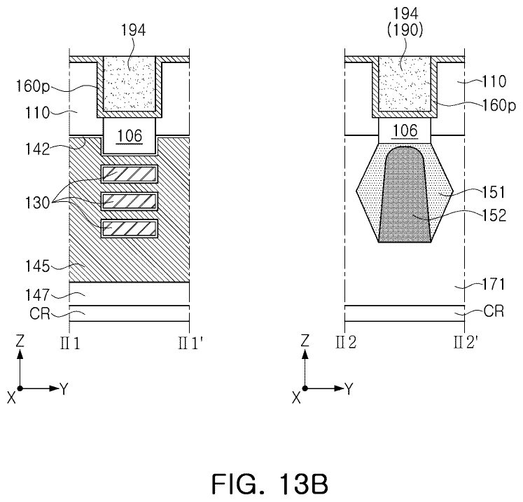

Subsequently, at least a portion of each of the exposed lower surface and side surface of the isolation layer 110 may be removed to form the third recess region RC3. A process of removing at least portion of the isolation layer 110 may be a process for securing a space for an intermediate insulating pattern 160 (see FIGS. 13A and 13B) formed in a subsequent process. Referring to FIG. 11B, the process of removing a portion of the isolation layer 110 may be performed in a direction of an arrow illustrated.

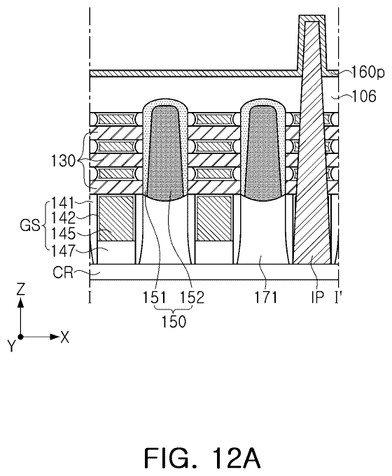

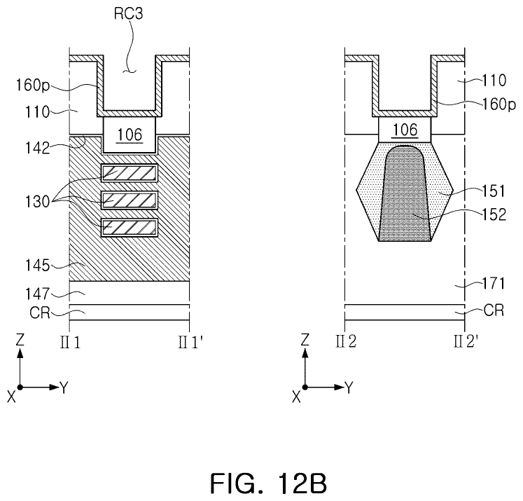

Referring to FIGS. 12A and 12B, a preliminary intermediate insulating pattern 160p, covering the exposed lower surface and side surface of the isolation layer 110, may be formed.

The preliminary intermediate insulating pattern 230p may be formed along a region from which a portion of the substrate 101 and the active pattern 105 is removed. The preliminary intermediate insulating pattern 230p may be formed to conformally cover the region. Specifically, the preliminary intermediate insulating pattern 160p may be formed along a surface in contact with a lower surface of the semiconductor pattern 105 and the exposed side and lower surfaces of the isolation layer 110 in the third recess region RC2. The preliminary intermediate insulating pattern 160p may be formed of a low-κ material, and may be formed of a material having a selectivity with silicon (Si). The preliminary intermediate insulating pattern 160p may include an insulating material, and may include at least one of SiO, SiN, SiCN, SiOC, SiON, and SiOCN, but inventive concepts are not limited thereto.

Referring to FIGS. 13A and 13B, a substrate insulating layer 190, disposed below the semiconductor pattern 106 and the preliminary intermediate insulating pattern 160p, may be formed.

The substrate insulating layer 190 may include a lower insulating pattern 194 surrounded by the preliminary intermediate insulating pattern 160p. The lower insulating pattern 194 may correspond to a fin structure protruding from an upper surface of the substrate insulating layer 190. A width of the lower insulating pattern 194 in the second direction (for example, the Y-axis direction) may be equal to a width of the semiconductor pattern 106 in the second direction. The lower insulating pattern 194 may form a fin-type structure together with the semiconductor pattern 106, and the preliminary intermediate insulating pattern 160p may extend along at least a portion of a side surface of the fin-type structure.

Referring to FIGS. 14A and 14B, a fourth recess region RC4, exposing a lower surface of the source/drain region 150, may be formed by removing a portion of the lower insulating pattern 194, the preliminary intermediate insulating pattern 160p, and the semiconductor pattern 106.

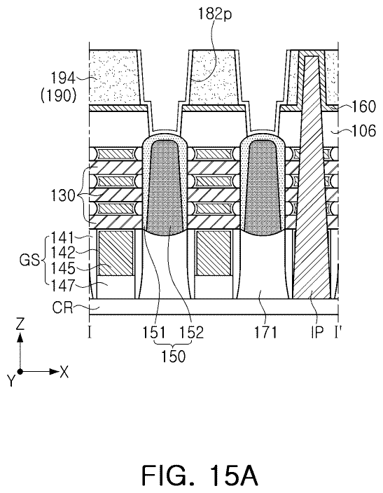

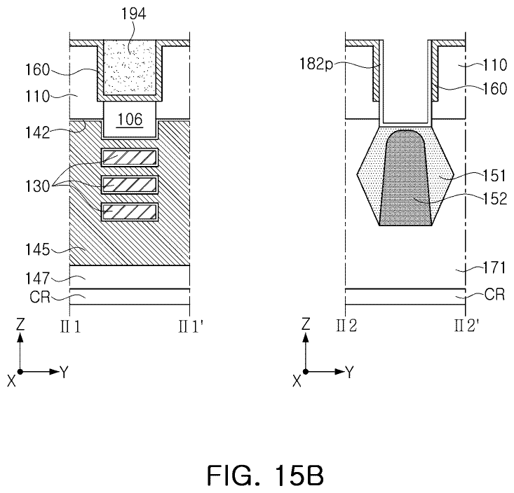

The fourth recess region RC4 may be formed to expose the lower surface of the source/drain region 150, specifically, a lower surface of the first epitaxial layer 151. A portion of the lower insulating pattern 194, forming the substrate insulating layer 190, may be removed. A process of removing a portion of the lower insulating pattern 194 may be performed in a direction of an arrow. The process may be performed to secure a space for forming an insulating liner layer 182 (see FIG. 15A) in a subsequent process. The intermediate insulating pattern 160 may be formed by removing a portion of the preliminary intermediate insulating pattern 160p overlapping the source/drain region 150 in a vertical direction.

Referring to FIGS. 15A and 15B, a preliminary insulating liner layer 182p may be formed in a region vertically overlapping the source/drain region 150.

The preliminary insulating liner layer 182p may be formed to conformally cover a side surface of the lower insulating pattern 194, a side surface of the semiconductor pattern 106, and a lower surface of the source/drain region 150 in the fourth recess region RC4 overlapping the source/drain region 150 in the vertical direction. The preliminary insulating liner layer 182p may extend to cover a lower surface of the lower insulating pattern 194 in a formation process, but may be removed using a chemical mechanical polishing (CMP) process or the like to extend to a level, the same as that of the lower surface of the lower insulating pattern 194.

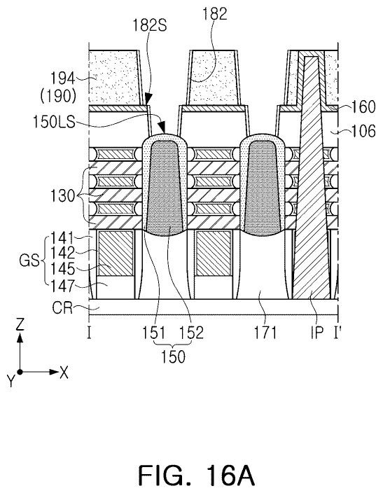

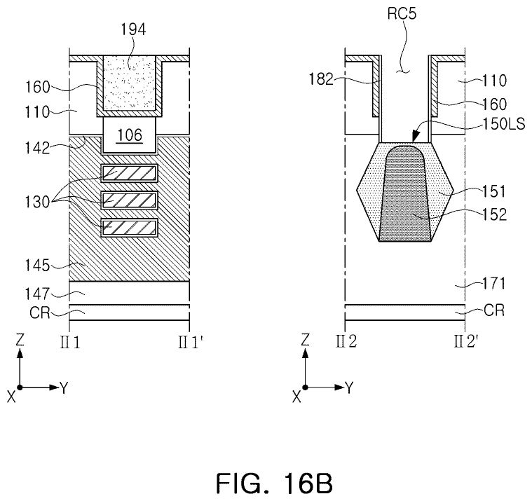

Referring to FIGS. 16A and 16B, a portion of the preliminary insulating liner layer 182p may be removed to form the insulating liner layer 182.

A portion of the preliminary insulating liner layer 182p may be removed using a dry etching process, a wet etching process, a CMP process, or the like. The formed insulating liner layer 182 may have a reduced thickness, as compared to the preliminary insulating liner layer 182p (see FIG. 15A). In a process of forming the insulating liner layer 182, at least a portion of a lower surface 182S of the intermediate insulating pattern 160 may be exposed, and at least a portion of a lower surface 150LS of the source/drain region 150 may be exposed.

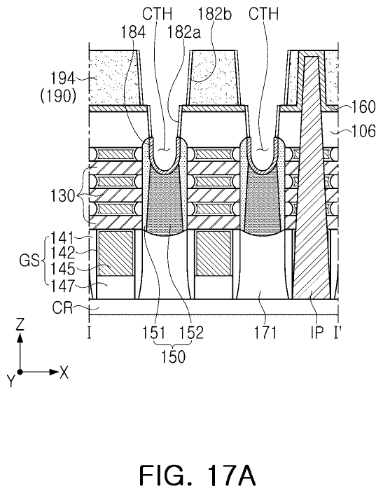

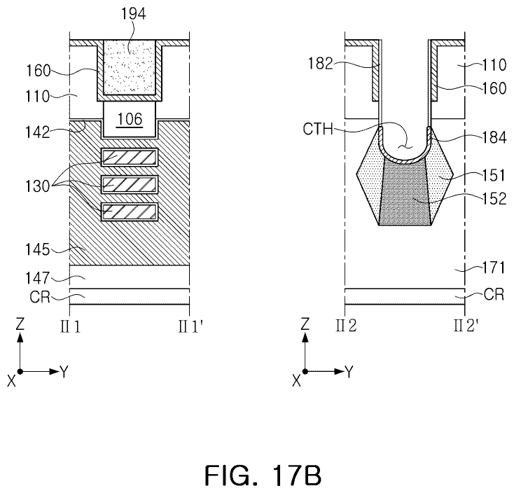

Referring to FIGS. 17A and 17B, a contact hole CTH may be formed, an exposed first epitaxial layer 151 may be partially removed, and a metal-semiconductor compound layer 184 may be formed.

The contact hole CTH may be formed to pass through the lower insulating pattern 194 and the semiconductor pattern 106 along a vertical region VR of the backside contact structure 180 of FIGS. 2A and 2B. The first epitaxial layer 151 may be exposed through the contact hole CTH. The second epitaxial layer 152 may be exposed by partially removing the first epitaxial layer 151 exposed below the contact hole CTH. Accordingly, an extension portion ES below the contact hole CTH may be further expanded to correspond to the contact region CR of FIGS. 2A and 2B.

The metal-semiconductor compound layer 184 may be formed by performing a metal-semiconductor process such as a silicidation process using the exposed source/drain region 150.

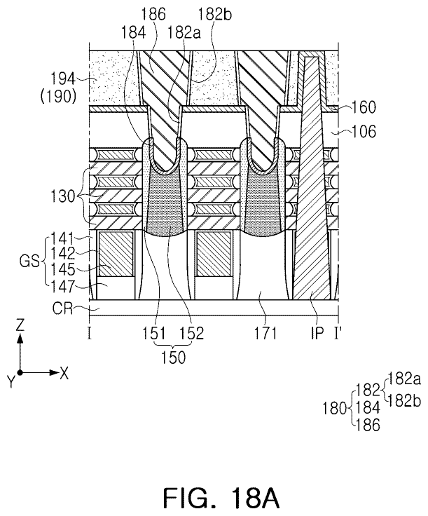

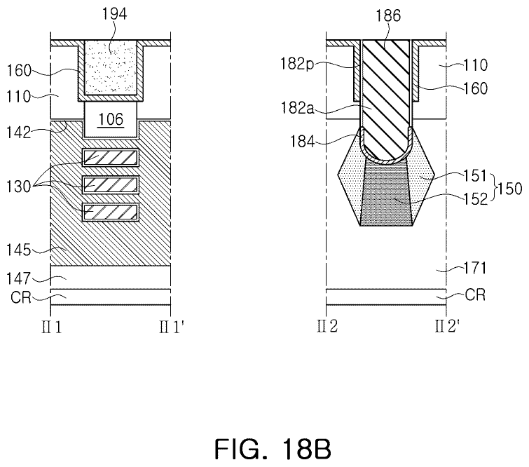

Referring to FIGS. 18A and 18B, a conductive layer 186 may be formed to form the backside contact structure 180.

The conductive layer 186 may be formed to fill the contact hole CTH. Accordingly, the backside contact structure 180, including the liner layer 182, the metal-semiconductor compound layer 184, and the conductive layer 186, may be formed. The conductive layer 186 may fill the contact hole CTH defined by the metal-semiconductor compound layer 184 and the insulating liner layer 182.

Referring to FIGS. 1, 2A, and 2B, the carrier substrate CR may be removed to manufacture the semiconductor device 100A. In a subsequent process, a backside power structure, electrically connected to the backside contact structure 180, may be additionally formed.

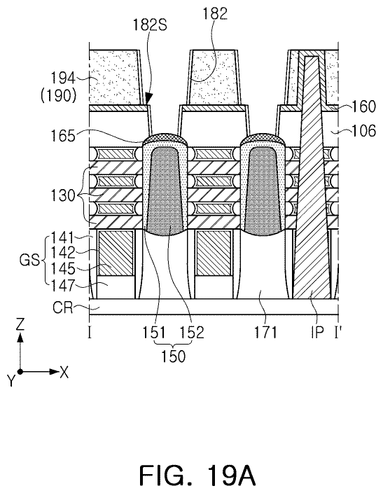

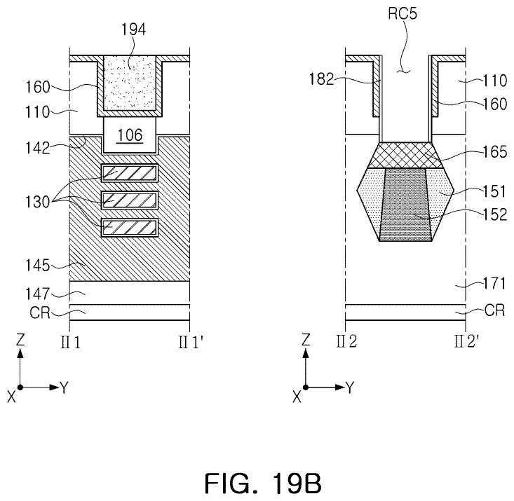

FIGS. 19A and 19B are diagrams illustrating processes in a method of manufacturing a semiconductor device according to example embodiments. FIGS. 19A and 19B may correspond to cross-sections of processes corresponding to FIGS. 14A and 14B.

Referring to FIGS. 19A and 19B, first, the processes described above with reference to FIGS. 5A to 13B may be performed in the same manner, and then a portion of the lower insulating pattern 194 may be removed to form a fourth recess region RC4. A lower material layer 165 may be positioned on a lower surface of the source/drain region 150. The lower material layer 165 may be formed prior to a process of forming the first epitaxial layer 151 and the second epitaxial layer 152. The lower material layer 165 may include a semiconductor material such as silicon germanium (SiGe) or the like, and may be a layer further including impurities, but inventive concepts are not limited thereto, and may include an insulating material. The lower material layer 165 may serve to perform self-aligning in a process of forming a recess region for forming the backside contact structure 180. The lower material layer 165 may include a high concentration of impurities, and may include a material having a selectivity different from those of the first epitaxial layer 151 and the second epitaxial layer 152. Accordingly, in a process of forming the fourth recess region RC4, the lower material layer 165 may also serve to protect the first epitaxial layer 151 and the second epitaxial layer 152 from being etched.

Subsequent processes may be performed according to a process sequence of FIGS. 15A to 18B, and the semiconductor device 100C according to an example embodiment of inventive concepts may be provided.

According to example embodiments of inventive concepts, a step structure may be introduced in which a width of a portion of a lower end of a backside contact structure is increased, such that a semiconductor device may have improved electrical properties.

While example embodiments have been shown and described above, it will be apparent to those skilled in the art that modifications and variations could be made without departing from the scope of inventive concepts as defined by the appended claims.

What is claimed is:

1. A semiconductor device comprising:
a substrate insulating layer including a lower insulating pattern having a fin structure extending in a first direction;
a semiconductor pattern extending in the first direction on the lower insulating pattern of the substrate insulating layer;
a plurality of channel layers stacked on the semiconductor pattern and spaced apart from each other in a direction perpendicular to an upper surface of the lower insulating pattern;
a gate structure surrounding the plurality of channel layers and extending in a second direction, the second direction intersecting the first direction;
a source/drain region on the semiconductor pattern and opposite sides of the gate structure, the source/drain region connected to side surfaces of the plurality of channel layers in the first direction;
a backside contact structure below the source/drain region, the backside contact structure including a contact region connected to the source/drain region, a first vertical region vertically extending below the contact region, and a second vertical region vertically extending below the first vertical region; and
an intermediate insulating pattern in contact with a lower surface of the semiconductor pattern, the intermediate insulating pattern overlapping a portion of the backside contact structure in a horizontal direction, wherein
the backside contact structure includes a metal-semiconductor compound layer, a first insulating liner layer, a second insulating liner layer, and a conductive layer,
the metal-semiconductor compound layer forms an external surface of the contact region,
the metal-semiconductor compound layer is in contact with the source/drain region,
the first insulating liner layer forms an external surface of the first vertical region,
the first insulating liner layer is in contact with the semiconductor pattern, the second insulating liner layer forms an external surface of the second vertical region,
the second insulating liner layer is in contact with the lower insulating pattern,
the conductive layer passes through each of the substrate insulating layer and the semiconductor pattern,
the conductive layer is in contact with each of the metal-semiconductor compound layer, the first insulating liner layer, and the second insulating liner layer, and
a step portion of the conductive layer is between the first vertical region and the second vertical region.

2. The semiconductor device of claim 1, wherein
the first vertical region is surrounded by the semiconductor pattern,
the first vertical region has a first width,
the second vertical region is surrounded by the substrate insulating layer,
the second vertical region has a second width, and
the second width is greater than the first width.

3. The semiconductor device of claim 2, wherein
the contact region has a third width, and
the third width is less than the first width.

4. The semiconductor device of claim 1, wherein
an angle formed by a lower surface of the second vertical region and a side surface of the second vertical region is less than an angle formed by a lower surface of the first vertical region and a side surface of the first vertical region.

5. The semiconductor device of claim 1, wherein the first vertical region and the second vertical region have a tapered shape toward the source/drain region.

6. The semiconductor device of claim 1, further comprising:
a lower material layer between the source/drain region and the semiconductor pattern, the lower material layer including silicon germanium (SiGe).

7. The semiconductor device of claim 6, wherein the lower material layer includes at least one of boron (B) and carbon (C) as impurities.

8. The semiconductor device of claim 6, wherein the source/drain region is not in contact with the semiconductor pattern.

9. The semiconductor device of claim 1, further comprising:
a lower insulating layer below the substrate insulating layer.

10. The semiconductor device of claim 1, wherein
the source/drain region includes a first epitaxial layer and a second epitaxial layer on the first epitaxial layer, and
the metal-semiconductor compound layer is in contact with the first epitaxial layer and the second epitaxial layer.

11. The semiconductor device of claim 1, wherein an upper surface of the first insulating liner layer is in contact with a lower surface of the metal-semiconductor compound layer.

12. The semiconductor device of claim 1, further comprising:
a power transmission line on a lower surface of the substrate insulating layer, wherein the power transmission line is connected to the backside contact structure.

13. The semiconductor device of claim 1, wherein the conductive layer is insulated from the semiconductor pattern.

14. The semiconductor device of claim 1, further comprising:
an isolation layer defining the semiconductor pattern, wherein
a level of an uppermost end of the intermediate insulating pattern is higher than a lowermost end of the isolation layer.

15. A semiconductor device comprising:
a substrate insulating layer;
a semiconductor pattern extending in a first direction on the substrate insulating layer;
a gate structure on the substrate insulating layer and extending in a second direction, the second direction intersecting the first direction;
source/drain regions on both sides of the gate structure;
a backside contact structure below a corresponding one of the source/drain regions,
the backside contact structure including a conductive layer passing through the substrate insulating layer and an insulating liner layer surrounding the conductive layer, the conductor layer being electrically connected to the corresponding one of the source/drain regions; and
an intermediate insulating pattern between the substrate insulating layer and the semiconductor pattern, the intermediate insulating pattern in contact with a portion of the conductive layer, wherein
a portion of the intermediate insulating pattern is between the substrate insulating layer and the semiconductor pattern and extends parallel to each of the semiconductor pattern and the substrate insulating layer, and
the portion of the conductive layer in contact with the intermediate insulating pattern is exposed from the insulating liner layer.

16. The semiconductor device of claim 15, wherein at least a portion of a lower surface of the intermediate insulating pattern is in contact with the conductive layer.

17. The semiconductor device of claim 15, wherein a thickness of the insulating liner layer is 5 nm to 7 nm.

18. The semiconductor device of claim 15, further comprising:
an insulating separation pattern extending parallel to the gate structure.

19. The semiconductor device of claim 18, wherein the intermediate insulating pattern surrounds a portion of the insulating separation pattern.

20. A semiconductor device comprising:
a substrate insulating layer;
a semiconductor pattern extending in a first direction on the substrate insulating layer;
a gate structure on the substrate insulating layer and extending in a second direction, the second direction intersecting the first direction;
source/drain regions on both sides of the gate structure and on the substrate insulating layer;
a backside contact structure below the source/drain regions,
the backside contact structure including a conductive layer passing through the semiconductor pattern and an insulating liner layer surrounding a portion of the conductive layer, the conductor layer being electrically connected to the source/drain region; and
an intermediate insulating pattern between the semiconductor pattern and the substrate insulating layer, wherein
a level of the intermediate insulating pattern is same as a level of a portion of the backside contact structure,
the intermediate insulating pattern is on an upper surface of the substrate insulating layer and side surfaces of the substrate insulating layer,
the insulating liner layer includes a first insulating liner layer and a second insulating liner layer,
a level of the second insulating liner layer is lower than a level of the first insulating liner layer, and
the second insulating liner layer is spaced apart from the first insulating liner layer.
